(19) United States
(12) Patent Application Publication
(10) Pub. No.: US 2012/0223730 A1
(43) Pub. Date: Sep. 6, 2012

(54) PROBE CARD POSITIONING MECHANISM AND INSPECTION APPARATUS

(75) Inventor: Hiroshi YAMADA, Nirasaki City (JP)

(73) Assignee: TOKYO ELECTRON LIMITED, Tokyo (JP)

(21) Appl. No.: 13/408,379

(22) Filed: Feb. 29, 2012

(30) Foreign Application Priority Data
Mar. 2, 2011 (JP) 2011-45338

(51) Int. Cl. G01R 31/00

(52) U.S. Cl. 324/750.16

(57) ABSTRACT

A probe card positioning mechanism in which, when a probe card used to inspect electrical characteristics of an object to be processed is detachably inserted in a head plate of an inspection apparatus or an insert ring fixed to the head plate, at least three positioning pins placed circumferentially with an interval therebetween on an outer circumference of the probe card are inserted in at least three corresponding positioning long holes formed in the head plate or the insert ring such that the probe card is positioned at a specified position of the head plate or the insert ring, wherein the positioning holes are formed as long holes being elongated in a width-wise direction of the probe card and the entire inner circumferential surface of the long holes is configured as a taper surface which is gradually declined along an insertion direction of the pins.

### CROSS-REFERENCE TO RELATED APPLICATION

This application claims the benefit of Japanese Patent Application No. 2011-045338, filed on Mar. 2, 2011, in the Japanese Patent Office, the disclosure of which is incorporated herein in their entirety by reference.

### TECHNICAL FIELD

The present disclosure relates to a probe card positioning mechanism and an inspection apparatus which are used to inspect electrical characteristics of objects to be processed such as semiconductor wafers, and more particularly, to a probe card positioning mechanism which is capable of mounting a probe card in an inspection apparatus without horizontal misalignment, and an inspection apparatus using the same.

### BACKGROUND

A conventional inspection apparatus includes a loader chamber L and a probe chamber P, which are adjacent to each other, for example, as shown in FIGS. 4 and 5. The loader chamber L includes a cassette receiving unit which receives a plurality of semiconductor wafers W in a cassette, a wafer carrying mechanism which carries the semiconductor wafers in/out of a cassette one by one, and a pre-alignment mechanism which pre-aligns the semiconductor wafers W while the wafer carrying mechanism is carrying the semiconductor wafers W. The probe chamber P includes a loading table (wafer chuck) 1 which holds a semiconductor wafer W and is movable in X, Y, Z and θ directions, a probe card 2 having a plurality of probes 2A contacting a plurality of electrode pads formed in the semiconductor wafer W on the wafer chuck 1, a clamp mechanism 4 (see FIG. 5) which clamps the probe card 2 through a card holder 3 (see FIG. 5), an insert ring 5 which mounts the probe card 2, a head plate 6 to which the insert ring 5 is fixed, and a controller. A test head T is electrically connected to the probe card 2 via a connection ring 8. In FIG. 4, reference numeral 7 denotes an alignment mechanism which aligns the semiconductor wafer W and the probe card 2 in cooperation with the wafer chuck 1 (reference numeral 7A denotes an upper camera and reference numeral 7B denotes a lower camera).

For inspection of the semiconductor wafer W, under control of the controller, the semiconductor wafer W is loaded from the loader chamber L onto the wafer chuck 1 within the probe chamber P, the wafer chuck 1 and the alignment mechanism 7 cooperate to align the plurality of electrode pads of the semiconductor wafer W with the plurality of probes 2A. Afterwards, electrical characteristics of a plurality of devices formed in the semiconductor wafer W are inspected by electrically connecting the plurality of electrode pads with the plurality of probes 2A.

The probe card 2 is positioned relative to the head plate 6 using a positioning mechanism 9, for example, as shown in FIG. 5. The positioning mechanism 9 includes three positioning pins 9A placed circumferentially with an interval therebetween on an outer circumference of the probe card 2 and three positioning holes 9B formed in the insert ring 5 corresponding to the pins 9A, as shown in FIG. 5. The positioning holes 9B are formed as circular holes each having an outer diameter larger than that of the pins 9A which are formed to be loosely inserted in the three corresponding holes 9B. By making the diameter of the positioning holes 9B larger than that of the pins 9A, the pins 9A can be reliably inserted in the holes 9B even if the probe card 2 or the insert ring 5 thermally expands or there is some misalignment between the probe card 2 and the insert ring 5.

In order to mount the probe card 2 on the insert ring 5, when the probe card 2 is moved in a certain direction to be placed immediately below the insert ring 5 and is lifted up from that position to be close to the insert ring 5, the positioning pins 9A are loosely inserted in the positioning holes 9B of the insert ring 5, and the outer circumference of the probe card 2 makes contact with the inner circumference of the insert ring 5. In this condition, the clamp mechanism 4 clamps the card holder 3 to mount and fix the probe card 2 to the insert ring 5.

Thereafter, prior to inspection of the semiconductor wafer W, the positions of tip portions of the plurality of probes 2A of the probe card 2 are detected as XYZ coordinates using the lower camera 7B of the alignment mechanism 7 and then probe-alignment is carried out.

However, in the above conventional inspection apparatus, although the probe card 2 is positioned relative to the insert ring 5 by means of the positioning mechanism 9 when the probe card 2 is mounted on the insert ring 5, since the pins 9A and the circular holes 9B acting as the positioning mechanism 9 have configuration that the pins 9A are loosely inserted in the circular holes 9B with a gap therebetween, the axial center of the pins 9A are horizontally deviated from the axial center of the holes 9B whenever the probe card 2 is mounted, as shown in FIG. 5, thereby dislocating the tip portions of the probes 2A whenever the probe card 2 is mounted. Accordingly, for repeated use of the probe card 2, there is a problem that probe-alignment has to be carried out whenever the probe card 2 is mounted. The same problem occurs when the temperature of the wafer chuck 1 is changed.

### SUMMARY

It is an object of the present disclosure to provide a probe card positioning mechanism which allows a probe card to be correctly mounted at a specified position of an insert ring or a head plate of an inspection apparatus without misalignment, and, particularly, for repeated use of the probe card, the subsequent probe-alignment to be omitted if probe-alignment is carried out once, and an inspection apparatus using the same.

According to one embodiment of the present disclosure, there is provided a probe card positioning mechanism in which, when a probe card used to inspect electrical characteristics of an object to be processed is detachably inserted in a head plate of an inspection apparatus or an insert ring fixed to the head plate, at least three positioning pins placed circumferentially with an interval therebetween on an outer circumference of the probe card are inserted in at least three corresponding positioning long holes formed in the head plate or the insert ring such that the probe card is positioned at a specified position of the head plate or the insert ring, wherein the positioning holes are formed as long holes having an elongated shape substantially extending in a width-wise direction of the probe card and the entire inner circumferential surface of the long holes is configured as a taper surface which gradually declines along an insertion direction of the pins.

According to another embodiment of the present disclosure, there is provided an inspection apparatus including a probe card used to inspect electrical characteristics of an object to be processed, an insert ring to support the probe card, and a head plate, wherein at least three positioning pins are placed circumferentially with an interval therebetween on an outer circumference of the probe card and at least three positioning long holes corresponding to the three positioning pins are formed in the head plate or the insert ring as a probe card positioning mechanism such that the probe card is positioned at a specified position of the head plate or the insert ring, wherein the positioning holes are formed as long holes having an elongated shape substantially extending in a width-wise direction of the probe card and the entire inner circumferential surface of the long holes is configured as a taper surface which is gradually declines along an insertion direction of the pins.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view showing main parts of an inspection apparatus according to one embodiment of the present disclosure.

FIGS. 2A to 2C are views showing a positioning mechanism used for the inspection apparatus shown in FIG. 1, FIG. 2A being a plan view showing a probe card including pins of the positioning mechanism, FIG. 2B being a plan view showing an insert ring including long holes of the positioning mechanism and a head plate, and FIG. 2C being an enlarged plan view showing the long holes shown in FIG. 2B.

FIGS. 3A and 3B are enlarged views showing a positioning mechanism used for the inspection apparatus shown in FIG. 1, FIG. 3A being a sectional view showing a section of an insert ring perpendicular to a circumferential direction and FIG. 3B being a sectional view showing sections of a probe card and an insert ring perpendicular to a radial direction.

FIG. 4 is a front view showing a conventional inspection apparatus with a partial cross-sectional view of a probe chamber.

FIG. 5 is a sectional view corresponding to FIG. 3A, which shows a positioning mechanism used for the inspection apparatus shown in FIG. 4.

### DETAILED DESCRIPTION

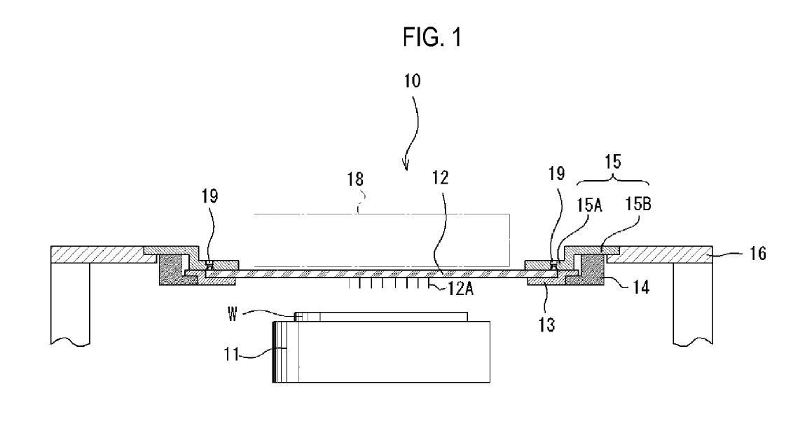

An embodiment of the present disclosure will now be described in detail with reference to FIGS. 1 to 3B. A difference in an inspection apparatus of this embodiment from a conventional inspection apparatus can be found in the positioning mechanism of a probe card. Therefore, the following description will be focused on characteristic parts of this embodiment.

As shown in FIG. 1, an inspection apparatus 10 of this embodiment includes a wafer chuck 11, a probe card 12, a clamp mechanism 14, an insert ring 15, a head plate 16, an alignment mechanism (not shown), a connection ring 18, and a positioning mechanism 19. The positioning mechanism 19 differs in configuration from a conventional inspection apparatus. As shown in FIG. 1, the insert ring 15 has a step between an inner circumference 15A and an outer circumference 15B, with the inner circumference 15A dented from the outer circumference. The inner circumference 15A of the insert ring 15 is inserted in a mount hole from the upper part of the head plate 16 and the outer circumference 15B is joined to the top surface of the head plate 16. The clamp mechanism 14 is placed at the bottom surface of the outer circumference 15B of the insert ring 15.

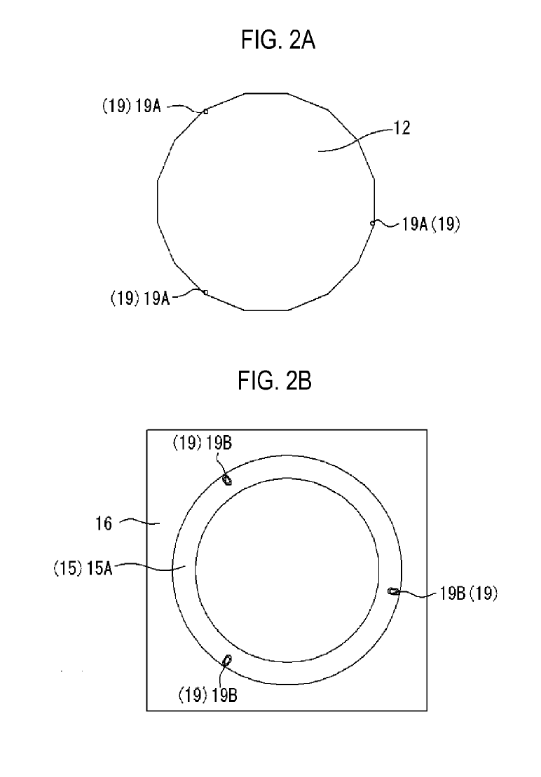

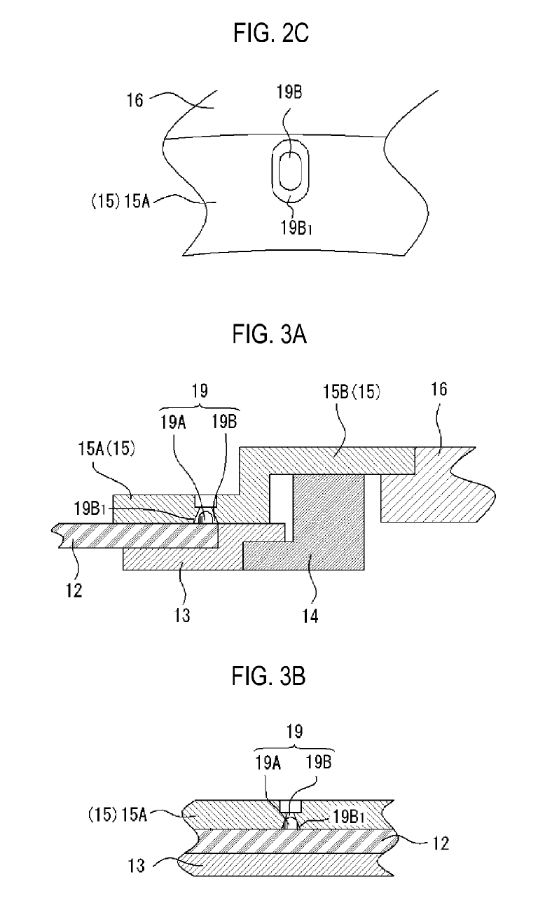

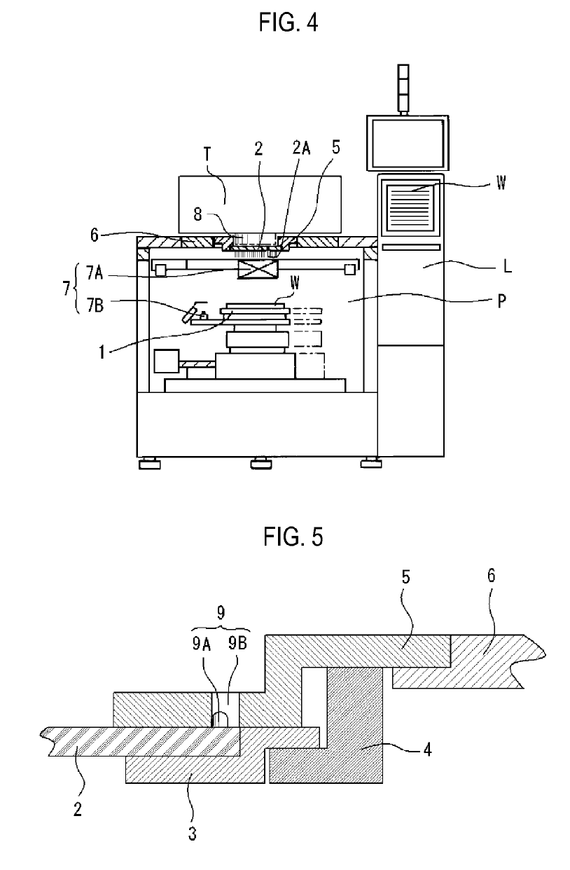

As shown in FIG. 1, the positioning mechanism 19 of this embodiment is placed in an outer circumference of the probe card 12 and the inner circumference 15A of the insert ring 15. As shown in FIGS. 2A and 2B, the positioning mechanism 19 includes three positioning pins (hereinafter abbreviated as “pins”) 19A placed circumferentially with an interval therebetween on the outer circumference of the probe card 12 and three positioning long holes 19B formed circumferentially with an interval therebetween in the inner circumference 15A of the insert ring 15 corresponding to pins 19A. The three pins 19A are fitted into the three corresponding long holes 19B. The three pins 19A are placed on the same circle formed with the probe card 12 and the three holes 19B are placed on the same circle formed with the inner circumference 15A of the insert ring 15.

As shown in FIGS, 3A and 3B, the three pins 19A have their respective spherical leading ends which are inserted and fitted into the three corresponding long holes 19B, and the outer circumference of the probe card 12 makes uniform contact with the inner circumference 15A of the insert ring 15 over the whole circumference.

As shown in FIG. 2C, the long holes 19B have a long axis formed to substantially extend in a width-wise direction of the probe card 12. The direction of the long holes 19B may not strictly coincide with the width-wise direction of the probe card 12 as long as both directions substantially coincide with each other. The inner circumferential surface of the long holes 19B is configured as a taper surface 19B₁ which has the largest opening end formed at the side of the probe card 12 and gradually declines along the insertion direction of the pins 19A. The opening end of the long holes 19B at the side of the probe card 12 has a short axis formed to be longer than the diameter of the pins 19A. An opening of the declined end of the long holes 19B has a short axis formed to be shorter than the diameter of the pins 19A and a long axis formed to be longer than the diameter of the pins 19A. Accordingly, when the three pins 19A are all inserted in the long holes 19, each of the spherical surface of the leading ends of the pins 19A point-contacts one pair of taper surfaces 19B₁ simultaneously in the long axis direction while the outer circumference of the probe card 12 and the inner circumference 15A of the insert ring 15 make uniform contact with each other. At this time, a gap is formed between one pair of taper surfaces 19B₁ in the short axis direction and the spherical surface of leading ends of the pins 19A, as shown in FIG. 3A That is, when the three pins 19A are inserted in the corresponding long holes 19B, the spherical surfaces of the leading ends of the pins 19A are constrained by point-contact with one pair of taper surfaces 19B₁ in the long axis direction in the three long holes 19B and are fitted into the corresponding long holes 19B without misalignment.

Accordingly, when the probe card 12 is positioned relative to the insert ring 15 through the positioning mechanism 19, the probe card 12 is constrained to a specified position to be mounted without misalignment in the X, Y and A directions and is clamped by the clamp mechanism 14 in the bottom of the head plate 16 with the center of the probe card 12 kept to coincide with the center of the insert ring 15. That is, the probe card 12 is mounted at a specified position relative to the insert ring 15 with high reproducibility.

The same probe card 12 can be attached/detached to/from the inspection apparatus 10 and used repeatedly. Accordingly, the probe card 12 is annexed with an identification symbol such as a bar code or the like. In addition, the inspection apparatus 10 is provided with a reader (not shown) which reads the identification symbol and information read by the reader is stored in a storage unit of the controller. For repeated use of the probe card 12, the identification symbol of the probe card 12 is beforehand read and the read information is stored in the storage unit before the probe card 12 is mounted to the insert ring 15. After the probe card 12 is mounted to the insert ring 15, probe-alignment of the probe card 12 is carried out and a result of detection thereof is stored in the storage unit in association with the identification symbol of the probe card 12. Accordingly, for repeated use of the probe card 12, the result of detection by the probe-alignment corresponding to the read information can be repeatedly used only by reading the identification symbol of the probe card 12 by means of the reader, thereby allowing the second and subsequent probe-alignment to be omitted. Even when temperature of the wafer chuck 11 is changed, the information on the probe card 12 stored in the storage unit can be used.

Next, the mount of the probe card 12 in the insert ring 15 will be described. First, the identification symbol of the probe card 12 is read by the reader and the read information is stored in the storage unit. Subsequently, after the three pins 19A of the positioning mechanism 19 are directed to the corresponding long holes 19B, for example, the probe card 12 is loaded on the wafer chuck 11 in the probe chamber and the probe card 12 is carried immediately below the insert ring 15 by the wafer chuck 11. The wafer chuck 11 is raised from that position to insert the three pins 19A of the probe card 12 in the three long holes 19B of the insert ring 15.

At this time, since the opening ends of the long holes 19B have a diameter larger than that of the pins 19A and the inner circumferential surface of the long holes 19B is configured as the taper surface 19B₁, the three pins 19A are smoothly inserted in the corresponding long holes 19B. When the wafer chuck 11 is fully raised, the outer circumference of the probe card 12 contacts the inner circumference 15A of the insert ring 15. At this time, since each of the spherical surfaces of leading ends of the three pins 19A point-contacts one pair of taper surfaces 19B₁ simultaneously in the long axis direction in the three corresponding long holes 19B and the motion of the probe card 12 in the horizontal direction is constrained, the probe card 12 is mounted in the insert ring 15 without horizontal misalignment and, at the same time, is clamped to the clamp mechanism 14 through the card holder 13 and thus is fixed relative to the insert ring 15.

Thereafter, probe-alignment of the probe card 12 mounted to the insert ring 15 is carried out as in the conventional art and a result of detection thereof is stored in the storage unit in association with the identification symbol of the probe card 12. Thereafter, electrical characteristics of the semiconductor wafer W are inspected as in the conventional art.

For reuse of the probe card 12, since the identification symbol is read by the reader prior to the mount of the probe card 12 to the insert ring 15 and the result of detection by the probe-alignment corresponding to the identification symbol can be used, there is no need to perform the probe-alignment again.

As described above, according to this embodiment, for the mount of the probe card 12 in the insert ring 15, when the three pins 19A of the positioning mechanism 19 are inserted in the three long holes 19B, since the three pins 19A point-contact one pair of taper surfaces 19B₁ in the long axis direction of the corresponding long holes 19B to constrain the motion of the probe card 12 in the horizontal direction, the probe card 12 can be always mounted at a specified position of the insert ring 15 with high precision without misalignment in the X, Y and θ directions. Accordingly, for repeated use of the same probe card, if the probe-alignment is carried out once when the probe card 12 is first mounted, the subsequent probe-alignment may be omitted. In addition, even when the temperature of the wafer chuck 11 changes, there is no need to perform the second and subsequent probe-alignment.

In addition, since the leading ends of the pins 19A are spherical, the pins 19A can be smoothly inserted in the long holes 19B along the taper surface 19B₁ of the long holes 19B so that the probe card 12 can be reliably mounted to the insert ring 15.

Although the three pins 19A and three long holes 19B of the positioning mechanism 19 have been illustrated in the above embodiment, the number thereof may be four or more. In addition, although in the above embodiment the long holes 19B have been formed in the insert ring 15, the long holes may be formed in the head plate depending on an installation structure of the probe card.

According to the present disclosure in some embodiments, it is possible to provide a probe card positioning mechanism which allows a probe card to be correctly mounted at a specified position of an insert ring or a head plate of an inspection apparatus without misalignment, and, particularly, for repeated use of the probe card, the subsequent probe-alignment to be omitted if probe-alignment is carried out once, and an inspection apparatus using the same.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A probe card positioning mechanism comprising:
a head plate; and
at least three positioning long holes formed in the head plate in which, when a probe card used to inspect electrical characteristics of an object to be processed is detachably inserted in the head plate of an inspection apparatus or an insert ring fixed to the head plate, at least three positioning pins placed circumferentially with an interval therebetween on an outer circumference of the probe card are inserted in the at least three positioning long holes formed in the head plate or the insert ring such that the probe card is positioned at a specified position of the head plate or the insert ring, wherein the at least three positioning long holes are formed as long holes having an elongated shape substantially extending in a width-wise direction of the probe card and the entire inner circumferential surface of the at least three positioning long holes is configured as a taper surface which gradually declines along an insertion direction of the pins.

2. The probe card positioning mechanism of claim 1, wherein a short axis in declined ends of the at least three positioning long holes is formed to be shorter than a diameter of the pins.

3. The probe card positioning mechanism of claim 1, wherein the leading ends of the pins have a spherical shape.

4. An inspection apparatus comprising a probe card used to inspect electrical characteristics of an object to be processed, an insert ring to support the probe card, and a head plate, wherein at least three positioning pins are placed circumferentially with an interval therebetween on an outer circumference of the probe card and at least three positioning long holes corresponding to the three positioning pins are located in the head plate or the insert ring as a probe card positioning mechanism such that the probe card is positioned at a specified position of the head plate or the insert ring, wherein the at least three positioning long holes are formed as long holes having an elongated shape substantially extending in a width-wise direction of the probe card and the entire inner circumferential surface of the at least three positioning long holes is configured as a taper surface which gradually declines along an insertion direction of the pins.

5. The inspection apparatus of claim 4, wherein a short axis in declined ends of the at least three positioning long holes is formed to be shorter than a diameter of the pins.

6. The inspection apparatus of claim 4, wherein the leading ends of the pins have a spherical shape.
